(19) United States
(12) Patent Application Publication
(10) Pub. No.: US 2015/0290713 A1
(43) Pub. Date: Oct. 15, 2015

(54) Methods for Producing Platelet Materials

(71) Applicants: Toni OLEJNIK, Cedar Lake, IN (US); Kurt EGBERS, Kent, OH (US)

(72) Inventors: Toni OLEJNIK, Cedar Lake, IN (US); Kurt EGBERS, Kent, OH (US)

(73) Assignee: Eckart America Corporation, Painesville, OH (US)

(21) Appl. No.: 14/427,924

(22) PCT Filed: Sep. 13, 2012
(86) PCT No.: PCT/US2012/055130

§ 371 Date: May 1, 2015

(51) Int. Cl. B22F 9/04; C09D 17/00; C23C 16/01; C23C 14/00; C23C 14/34; C23C 16/06

(52) U.S. Cl. CPC B22F 9/04; C23C 14/34; C23C 16/06; C23C 16/01; C23C 14/0005; C09D 17/00; C09D 17/006; C09D 17/002

(57) ABSTRACT

Processes for forming platelet materials, such as flakes, including but not limited to, metal flakes, such as aluminum flakes, are described. The processes involve the application of a release system to a support or drum which is subsequently dissolved to release one or more non-dissolving layer(s), such as one or more metal layer(s), formed thereon. A particular group of dispersing agents are described which when incorporated in the release system, lead to improved process efficiency and more consistent product. Additional features and aspects of the processes are described.

### BACKGROUND OF THE INVENTION

1. Field of the Invention

This invention relates to methods for producing materials in the form of flakes or platelets, such as effect pigments, that can be used for various functional and decorative applications. The flakes can be metal, metal compounds, non-metal or clear flakes. Functional applications of the flakes include uses in protective coatings in which the flakes can add a level of rigidity to produce certain desired properties of the finished coating, or in which the flake layer can be used to screen out light of certain wavelengths to protect an underlying pigmented layer. Reflective metal flakes are useful in a variety of optical or decorative applications, including inks, paints or coatings. Other uses of the flakes include microwave and electrostatic applications, together with chemical process and biological applications. The present invention also relates to effect pigment dispersions, in which the effect pigments thereof have a flake or platelet form.

2. Description of the Related Art

Conventional aluminum flake is typically manufactured in a ball mill containing steel balls, aluminum metal, mineral spirits, and a fatty acid usually stearic or oleic. The steel balls flatten the aluminum and break it into flakes. When the ball milling is complete the slurry is passed through a mesh screen for particle sizing. Flakes too large to pass through the screen are returned to the ball mill for further processing. Flake of the proper size is passed through the screen and introduced to a filter press where excess solvent is separated from the flake. The filter cake is then let down with additional solvent. Such conventional aluminum flake typically has a particle size from about 2 to about 200 microns and a particle thickness from about 0.1 to about 2.0 microns. These flakes are characterized by high diffuse reflectance, low specular reflectance, rough irregular flake micro surface, and a relatively low aspect ratio.

Another process for making metal flakes is a process of Avery Dennison Corporation for making flakes sold under the designation METALURE®. In this process one or both sides of a carrier sheet are gravure coated with a solvent-based resin solution. The dried coated web is then transported to a metalizing facility where one or both sides of the coated sheet are metalized by a thin film of vapor deposited aluminum. The sheet with the thin metal film is then returned to the coating facility where one or both sides of the aluminum are coated with a second film of the solvent-based resin solution. The dried coated/metal sheet is then transported again to the metallizing facility to apply a second film of vapor deposited aluminum to one or both sides of the sheet. The resulting multilayer sheet is then transported for further processing to a facility where the coatings are stripped from the carrier in a solvent such as acetone. The stripping operation breaks the continuous layer into particles contained in a slurry. The solvent dissolves the polymer out from between the metal layers in the slurry. The slurry is then subjected to sonic treatment and centrifuging to remove the solvent and the dissolved coating, leaving a cake of concentrated aluminum flakes approximately 50 to 65% solids. The cake is then let down in a suitable vehicle and further sized by homogenizing into flakes of controlled size for use in inks, paints, and coatings. Metal flakes produced by this process for use in printable applications such as inks are characterized by a particle size from about 4 to 20 microns and a thickness from about 150 to about 250 or to about 400 angstroms. Coatings made from these flakes have a high specular reflectance and a low diffuse reflectance. The flakes have a smooth mirror-like surface and a high aspect ratio. The coatings also have a high level of coverage per pound of flake applied when compared with metal flakes produced by other processes.

Flakes also are produced in a polymer/metal vacuum deposition process in which thin layers of vapor deposited aluminum are formed on a thin plastic carrier sheet such as polyester or polypropylene, with intervening layers of crosslinked polymers between the vapor deposited aluminum layers. The cross-linked polymer layers are typically a polymerized acrylate deposited in the form of a vaporized acrylate monomer. The multi-layer sheet material is ground into multilayer flakes useful for their optical properties. Coatings produced from such multi-layer flakes tend to have a high diffuse reflectance and a low specular reflectance. The flakes have a low aspect ratio and undesired low opacity when made into an ink.

In screen printing inks, the use of physical vapor deposition-(PVD)-metal pigments sometimes results in the appearance of undesirable “pin-holes.” Screen printing inks pigmented with PVD-metal effect pigments occasionally and undesirable clog (or foul) the sieves through which they are passed. As a result, the sieves must be cleaned, which delays the printing process.

One objective of the present invention is to reduce the number of manufacturing steps and the resulting cost of making highly reflective metal flakes, although the process also reduces the cost of making other flake-like materials described herein.

Another object of the present invention is to provide pigment dispersion which offer advantages, such as reduced or minimal pin-holes, in printing inks, such as screen-printing inks.

In addition to metal flakes, there are many industrial uses of glass (SiO₂) flakes. Conventional glass flakes generally have a thickness range of about 1 to 6 microns and a diameter from about 30 to about 100 microns. These glass flakes can be used for additions to polymers and coatings to improve various functional properties. These include addition of glass flakes as additives to produce thinner, smoother coatings, for example. One objective of this invention is to produce very thin, flat, smooth flakes, such as metal or glass flakes, for example, for use of their various functional properties in polymers, coatings and films.

### SUMMARY OF THE INVENTION

The difficulties and drawbacks associated with previously known techniques are addressed in the present invention.

In accordance with non-limiting aspect, the invention provides a method for producing metal flakes, platelets, and/or particles, such as effect pigments. The method comprises providing a substrate, and applying a release system to the substrate. The release system comprises (i) solvent, (ii) at least one polymeric release agent, and (iii) a dispersing agent (or dispersant), which in some embodiments is a salt of a sulfonic acid, to thereby form a release layer. The sulfonic acid, with some embodiments, comprises an alkyl group, an aryl group, or an alkyl-aryl group. The method also comprises applying a metal layer to the release layer, removing the metal layer, and subjecting the metal to one or more particle size control operations to thereby produce the metal flakes, platelets, and/or particles.

In another non-limiting aspect, the invention provides metal flakes, platelets, and/or particles produced by the noted method. Particulates, such as effect pigments, produced as described herein exhibit an array of beneficial characteristics. A significant advantage of the particulates is a relatively narrow distribution of particle size and thus a corresponding reduction in the amount of undesirable excessively large particles.

In accordance with the present invention there is further provided, an effect pigment dispersion comprising, (a) an effect pigment, present in an amount of 4 to 25 percent by weight, based on total weight of the effect pigment dispersion. The effect pigment has a form selected from flake forms, platelet forms, and/or particle forms. The effect pigment dispersion further comprises, (b) residues of a release layer comprising: (i) a polymeric release agent, present in an amount of 1 to 15 percent by weight, based on total weight of said effect pigment; and (ii) a dispersing agent, present in an amount of 0.025 to 1.5 percent by weight, based on total weight of said effect pigment. The effect pigment dispersion further comprises, (c) a solvent, or mixture of solvents, present in an amount providing a balance of 100 percent by weight, based on total weight of said effect pigment dispersion. With some embodiments, the residues of the release layer reside on at least one surface of the effect pigment.

As will be realized, the invention is capable of other and different embodiments and its several details are capable of modifications in various respects, all without departing from the invention. Accordingly, the drawings and description are to be regarded as illustrative and not restrictive.

### BRIEF DESCRIPTION OF THE DRAWINGS

FIG. 1 is a schematic functional block diagram illustrating a prior art process for manufacturing metal flakes;

FIG. 2 is a representative schematic elevational view illustrating a vacuum deposition chamber for applying a multi-layer coating in accordance with a non-limiting embodiment of the method of the present invention;

FIG. 3 is a representative schematic cross-sectional view illustrating a sequence of layers in a non-limiting embodiment of the multi-layer sheet material according to the invention;

FIG. 4 is a representative schematic cross-sectional view illustrating a multi-layer sheet material made according to a further non-limiting embodiment of the invention;

FIG. 5 is a representative functional block diagram schematically illustrating processing steps in accordance with a non-limiting embodiment of the method of the present invention;

FIG. 6 is a representative schematic cross-sectional view illustrating single layer flakes made by a non-limiting embodiment of the method of the present invention;

FIG. 7 is a representative schematic cross-sectional view of multi-layer flakes made by another non-limiting embodiment of the method of the present invention;

FIG. 8 is a representative schematic elevational view illustrating another non-limiting embodiment of the method for producing metal flakes in accordance with the present invention; and

FIG. 9 is a representative functional block diagram schematically illustrating processing steps for making flakes from multi-layer material made according to a non-limiting embodiment of the method of the present invention.

### DETAILED DESCRIPTION OF THE EMBODIMENTS

As used herein the term “platelet like” means a material, such as a pigment, such as an effect pigment, that has a platelet form, or is in the form of a platelet.

As used herein the term “platelet” means a material having a ratio of diameter (or width) to thickness that is greater than 1:1, such as from 1.5:1 to 1000:1.

As used herein, the term “flake like” means a material, such as a pigment, such as an effect pigment, that has a flake form, or is in the from of a flake.

As used herein the term “flake” means a material having a ratio of diameter (or width) to thickness that is greater than 1:1, such as from 1.5:1 to 1000:1.

With some embodiments of the present invention, the terms flake and platelet are equivalent and used interchangeably.

As used herein, the term “d50” with regard to particle size, such as but not limited to particle size of effect pigments, means the cumulative frequency distribution of the volume-averaged size distribution function as determined for the particles.

As used herein, the term “C₁-C₂₀ linear, branched, or cyclic alkyl” means C₁-C₂₀ linear alkyl, C₃-C₂₀ branched alkyl, and C₃-C₂₀ cyclic alkyl. The term “cyclic alkyl” includes monocyclic alkyl, fused ring cyclic alkyl, and/or polycyclic alkyl.

As used herein, the term “(meth)acrylic” and similar terms such as “(meth)acrylate” means acrylic and/or metharylic, and acrylate and/or methacrylate.

As used herein, the term “(meth)acrylic polymer” means (meth)acrylic homopolymers and/or (meth)acrylic copolymers, which in each case can include residues (or monomer units) of (meth)acrylic acid. The term “(meth)acrylic acid” as used herein meaning acrylic acid and/or methacrylic acid.

As used herein the term “(meth)acrylamide” means acrylamide and/or methacrylamide.

A process for making functional or decorative flakes or platelets economically and at high production rates includes, in accordance with some embodiments of the present invention, forming a multi-layer sandwich of vapor deposited metal and release coat(s) in alternating layers on a rotating chilled drum or suitable carrier medium contained in (or within) a vapor deposition chamber. The alternating metalized layers are applied by vapor deposition and the intervening release layers are, with some embodiments, solvent soluble thermoplastic polymeric materials applied by vapor deposition sources contained in the vapor deposition chamber. The multi-layer sandwich built up in the vacuum chamber is removed from the drum or carrier and treated with a suitable organic solvent to dissolve the release coating from the metal in a stripping process that leaves the metal flakes, with, concentrations of a residue the release system from 1 to 15 weight percent, referred to the metal pigment. In further embodiments the concentration of a residue the release system is from 4 to 12 weight percent. The solvent and dissolved release material are then removed by centrifuging to produce a cake of concentrated flakes which can be air milled and let down in a preferred vehicle and further sized and homogenized for final use in various applications, such as, but not limited to, inks, paints, and coatings. In accordance with some embodiments, the finished flakes include single-layer thin metal or metal alloy flakes or flakes of inorganic materials. In accordance with further embodiments, flakes are coated on both sides with one or more protective polymeric coatings that are applied from suitable vacuum deposition sources or the like contained in the vapor deposition chamber.

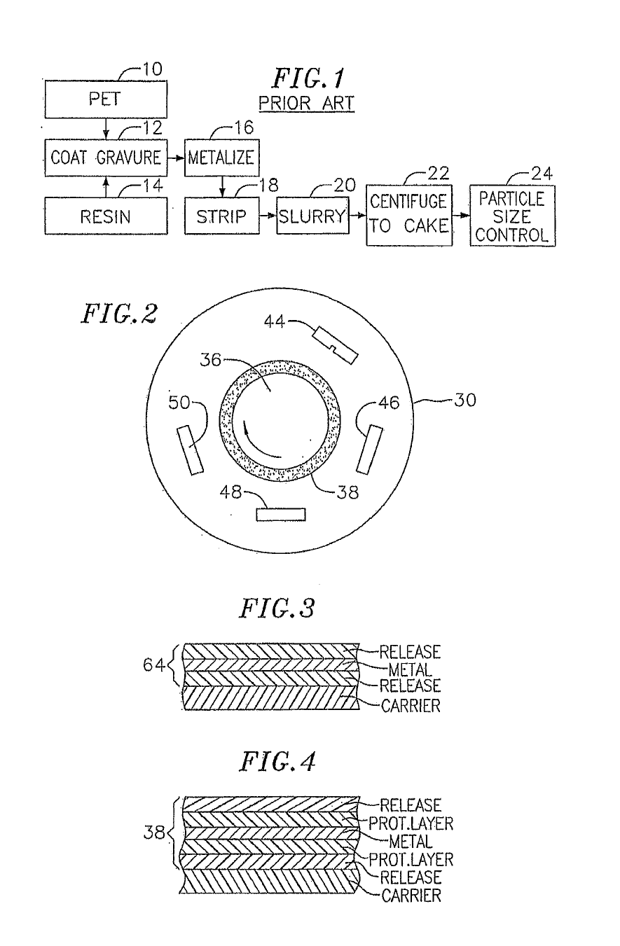

For purposes of non-limiting illustration with regard to certain aspects of the present invention, reference is made to FIG. 1 which illustrates a prior art process for making metal flakes according to a process utilized by Avery Dennison Corporation for manufacturing flakes sold under the designation METALURE®. According to this prior art process, both sides of a polyester carrier sheet 10 are gravure coated at 12 with a solvent-based resin solution 14. The dried coated web is then transported to a metalizing facility 16 where both sides of the coated and dried carrier sheet are metalized with a thin film of vapor deposited aluminum. The resulting multi-layer sheet is then transported for further processing to a facility at 18 where the coatings are stripped from the carrier in a solvent, such as but not limited to acetone, to form a solvent-based slurry 20 that dissolves the coating from the flakes. The slurry is then subjected to sonic treatment and centrifuging to remove the acetone and dissolved coating, leaving a cake 22 of concentrated aluminum flakes. The flakes are then let down in a solvent and subjected to particle size control at 24, such as, with some embodiments, by homogenizing.

This process has proved highly successful in producing extremely thin metal flakes of high aspect ratio and high specular reflectance. Aspect ratio is the ratio of average particle size divided by average particle thickness. Despite the success of the process for producing METALURE® flakes, it would be desirable to reduce production costs because additional processing must typically be performed to reduce the occurrence of excessively sized particles or flakes or agglomerations of such which collect on a filter screen in the particle size control operations. Moreover, for certain applications, the METALURE® product is not a suitable candidate because of the presence of a large particle size tail. As used herein, and in accordance with some embodiments the term “large particle size tail” and similar terms means flakes, platelets, and/or particles that are unable to pass through an 80 mesh screen.

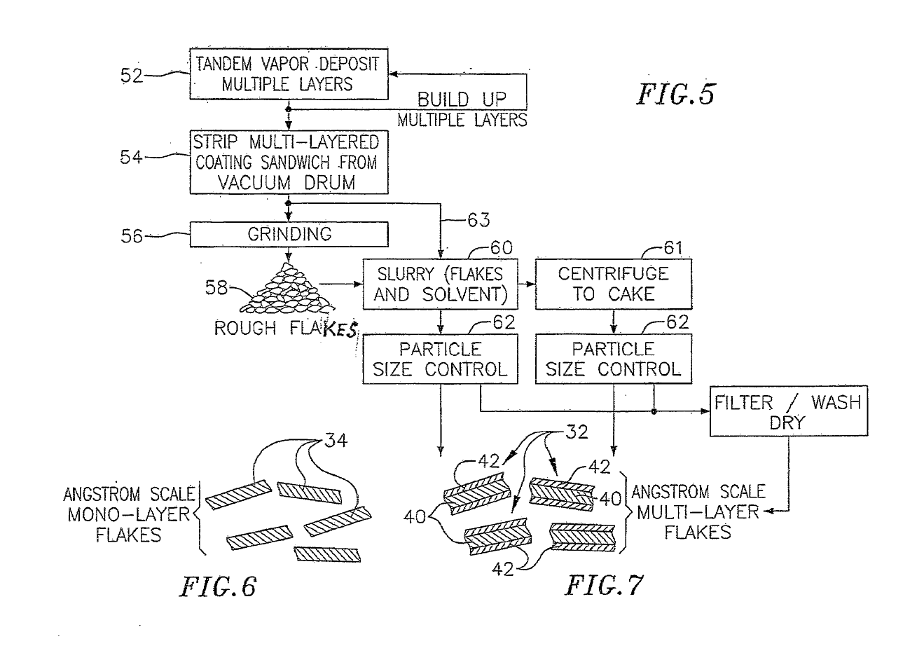

FIGS. 2 to 5 are illustrative of a non-limiting embodiment of a process for making the metal flakes shown in FIGS. 6 and 7. This process also can be used for making glass flakes, and also can be used for making nanospheres. FIG. 2 illustrates a vacuum deposition chamber 30 which contains suitable coating and metallizing equipment for making the multi-layer coated flakes 32 of FIG. 7. Alternatively, certain coating equipment in the vacuum chamber of FIG. 2 can be deactivated for making the single layer flakes 34 of FIG. 6, as will become apparent from the description to follow.

Referring again to FIG. 2, the vacuum deposition chamber 30 includes a vacuum source (not shown) used conventionally for evacuating such deposition chambers. With some embodiments, the vacuum chamber also includes an auxiliary turbo pump (not shown) for maintaining the vacuum at necessary levels within the chamber, without breaking (or releasing) the vacuum. The chamber also includes a chilled polished metal drum 36 on which a multilayer sandwich 38 is produced. This non-limiting embodiment of the invention will first be described with reference to making the flakes 32 of FIG. 7 which, in accordance with some embodiments, include an internal metalized film layer 40 and outer layers 42 of a protective coating bonded to both sides of the interposed metal film. The protective coating can, with some embodiments, include an inorganic material and/or a polymeric material, both of which are vapor deposited under vacuum.

The vacuum deposition chamber includes suitable coating and vapor deposition sources circumferentially spaced apart around the drum for applying to the drum a solvent soluble or dissolvable release coating, a protective outer coating, a metal layer, a further protective outer coating for the metal layer, and a further release layer, in that order. More specifically and in accordance with some embodiments, these sources of coating and deposition equipment contained (or residing) within the vacuum deposition chamber include (with reference to FIG. 2) a release system source 44, a first protective coating source 46, a metalizing source 48, and a second protective coating source 50. These coating and/or deposition sources are spaced circumferentially around the rotating drum so that as the drum rotates, thin layers can be built up to form the multi-layered coating sandwich 36 such as, for example, in sequence: release-coating-metal-coating-release-coating-metal-coating-release, and so on. This sequence of layers built up in the multi-layer sandwich 38 is illustrated schematically in FIG. 4 which also illustrates the drum 36 as the carrier in that instance. In FIG. 4, the term “PROT. LAYER” means protective layer, the term “RELEASE” means release layer, and the term “METAL” means metal layer.

In accordance with some embodiments, the release coating is either solvent-soluble or dissolvable, with some embodiments, but is capable of being laid down as a smooth uniform barrier layer that separates the metal or glass flake layers from each other, provides a smooth surface for, depositing the intervening metal or glass flake layers, and can be separated such as by dissolving it when later separating the metal or glass flake layers from each other. The release coating is, with some embodiments, a dissolvable thermoplastic polymeric material having a glass transition temperature (Tg) or resistance to melting that is sufficiently high so that the heat of condensation of the deposited metal layer (or other flake layer) will not melt the previously deposited release layer. With some embodiments, the previously deposited release layer is substantially resistant to (and with some further embodiments is substantially free of) melting through its entire thickness when a metal layer is deposited thereover. The release coating must, with some embodiments, withstand the ambient heat within the vacuum chamber in addition to the heat of condensation of the vaporized metal or glass flake layer. The release coating is applied, with some embodiments, in layers to interleave various materials and stacks of materials so as to allow them to be later separated by solubilizing the release layer. A release layer as thin as possible is desired, with some embodiments, because it is easier to dissolve and leaves less residue in the final product. Compatibility with various printing and paint systems also is desirable, with some embodiments. The release coating is solvent-soluble, such as a thermoplastic polymer with some embodiments, which is dissolvable in an organic solvent.

In accordance with some embodiments, the release coating source 44 includes suitable coating equipment for applying a polymeric material as a hot melt layer or for extruding the release coat polymer directly onto the drum. With some further embodiments, the release coat equipment includes a vapor deposition source that vaporizes a suitable monomer or polymer, and which deposits it on the drum or sandwich layer. Non-limiting examples of vapor deposition equipment for applying the polymeric release coat to the deposition surface are described herein. The release material freezes to solidify when or after it contacts either the chilled drum or the multi-layer sandwich previously built up on the chilled drum. The multi-layer film built up on the drum has a thickness sufficient to enable the chilled drum to draw enough heat through the film so as to be effective in solidifying the release coat being deposited on the outer surface of the metal or glass flake layer. With some further embodiments, an alternative polymeric release coating material is selected from lightly cross-linked polymeric coatings which, while not soluble, will swell in a suitable solvent and separate from the metal flake material or glass flake material. In accordance with some additional embodiments, a dissolvable release material includes or is selected from a polymeric material which has been polymerized by chain extension, rather than by cross-linking.

In accordance with some embodiments of the present invention, polymeric release coatings include styrene polymers, acrylic resins, or blends or combinations thereof. Release materials can, with some embodiments, be selected from cellulosic materials that are capable of being coated or evaporated without detrimentally affecting the release properties. Additional details and aspects of release systems according to various non-limiting embodiments of the present invention, including solvents and the use of particular additives, are described in further detail herein.

With further reference to the process of making flakes represented by FIG. 2, and following application of the release coating, the drum travels past the first protective coating source 46 for applying a protective layer to the release coat. Each protective layer with some embodiments, is formed from a vapor deposited functional monomer, such as but not limited to ethylenically unsaturated materials, such as but not limited to one or more acrylate and/or methacrylate monomers, which is then cured by exposure to actinic radiation, such as, but not limited to, electron beam (EB) radiation, which results in cross-linking or polymerizing the coating material. With some further embodiments, the protective layer is a thin layer of radiation cured polymer, which can be later broken up into flakes. In accordance with some alternative embodiments, the protective layer is a vapor deposited inert, insoluble inorganic or glass flake material which forms a hard clear coat that bonds to both sides of the metal layer. With some embodiments, the protective coatings or layers are hard impervious materials, which can be deposited in alternating layers with metals, such as aluminum, so as to provide a desirable level of wear resistance, weatherability protection, and water and acid resistance. Non-limiting examples of such protective materials are described herein.

The rotating drum next transports the coating past the metalizing source 48 for vapor depositing a layer of metal, such as aluminum, on the underlying coating layer. A number of metals or inorganic compounds can be deposited as a thin film interleaved by other materials and release layers so they can be later separated into thin metallic flakes or inorganic flakes. In addition to aluminum, such materials include, but are not limited to, copper, silver, chromium, nichrome, tin, zinc, indium, zinc sulfide, alloys of two or more thereof, and combinations of two or more thereof. The most preferred metal is aluminum. The metal coatings, with some embodiments, include multi-directional reflection enhancing stacks, such as layers of highly reflective materials, or optical filters made by depositing suitable layers of controlled thickness and index of refraction.

The rotating drum next transports the stack past the second coating source 50 for subsequent application of a protective coating layer (that is similar or different to the previously applied protective coating layer) to the metallized film, such as by vapor deposition and curing of a hard protective polymeric material, or vapor depositing an inorganic material.

With some embodiments, further rotation of the drum next transports the sandwich material full circle again past the release coat source 44 and so on in sequence, which results in build up of the coated metal layers.

Inorganic materials, such as but not limited to oxides and fluorides, are with some embodiments vapor deposited by the deposition source 48 so as to produce thin layers that can be separated and made into flakes. Such coatings include, but are not limited to, magnesium fluoride, silicon monoxide, silicon dioxide, aluminum oxide, aluminum fluoride, indium tin oxide, titanium dioxide, and combinations of two or more thereof.

Suitable deposition sources include, but are not limited to, electron beam (EB), resistance, sputtering and plasma deposition techniques for vapor depositing thin coatings of metals, inorganics, glass flake materials and polymers.

Once the multi-layer sandwich is produced in the vacuum deposition chamber, it is then ready to be removed from the drum and subjected to further processing illustrated in FIG. 5.

The continuous process of building up the multi-layer sandwich is depicted at item 52 in FIG. 5. The multi-layer sandwich is then stripped from the drum at 54 by a process in which the layers that are separated by the releasing material are broken apart into individual layers. The sandwich layers may be stripped by introducing them directly into an organic solvent, or by crushing and grinding or scraping. In the illustrated embodiment, the multi-layer sandwich is subjected to grinding at 56 to produce rough flakes 58. The rough flakes are then mixed with a suitable solvent in a slurry 60 for dissolving the release coat material from the surfaces of the multi-layer flakes 32. Alternatively, the multi-layer sandwich may be stripped from the drum and broken into individual layers by a step 63 of introducing the layered material directly into the solvent at 60. The release coat material applied in the vacuum deposition chamber is selected so that the release material is dissolvable from the flakes by the solvent in the slurry process. In accordance with some embodiments, the slurry is subjected to a centrifuging step 61 so that the solvent or water is removed to produce a cake of concentrated flakes. The cake of concentrated flakes then can be let down in a suitable vehicle, in a particle size control step 62, to be further sized and homogenized for final use of the flakes in applications, such as but not limited to, inks, paints or coatings. Alternatively, the flakes can be let down in a solvent (without centrifuging) and subjected to particle size control at 62. In accordance with some embodiments, the metal layer(s) once removed, are sufficiently in a particulate or flake form and do not require further processing or sizing operations.

In accordance with some alternative processing embodiments, the multi-layer sandwich is removed from the drum and fluid milled or otherwise reduced to a small particle size, followed by treating this material in a two-step solvent process. The fluid used in fluid milling, with some embodiments, is selected from one or more gasses, such as air or an inert gas, such as nitrogen or carbon dioxide. First a small amount of solvent is used to begin the swelling process in dissolving the release coat layers, with some embodiments. A different second solvent is then added as a finished solvent for completing the release coat dissolving process and for enhancing compatibility with the finished ink or coating, in accordance with some embodiments. This process avoids subsequent centrifuging and homogenization steps, with some embodiments.

In accordance with some alternative embodiments for utilizing the vacuum chamber 30 equipment of FIG. 2, the protective coating sources 46 and 50 are omitted and the process is used for making the single layer flakes 34 shown in FIG. 6. In accordance with such embodiments, the build up of layers on the drum 36 to form the multi-layer sandwich 38 includes successive layers of release-metal-release-metal-release, and so on, as illustrated at 64 in FIG. 3. In accordance with some alternative embodiments, the single layer flakes can include layers of an inorganic or glass flake material as described herein.

Many different materials and stacks of materials can be constructed in which they are sandwiched by the soluble release layers that allow them to be separated from each other by solubilizing the release material. Examples of such constructions include, but are not limited to: (1) release/metal/release; (2) release/protective layer/metal/protective layer/release; (3) release/nonmetal layer/release; and (4) release/multidirectional reflection enhancing stack/release.

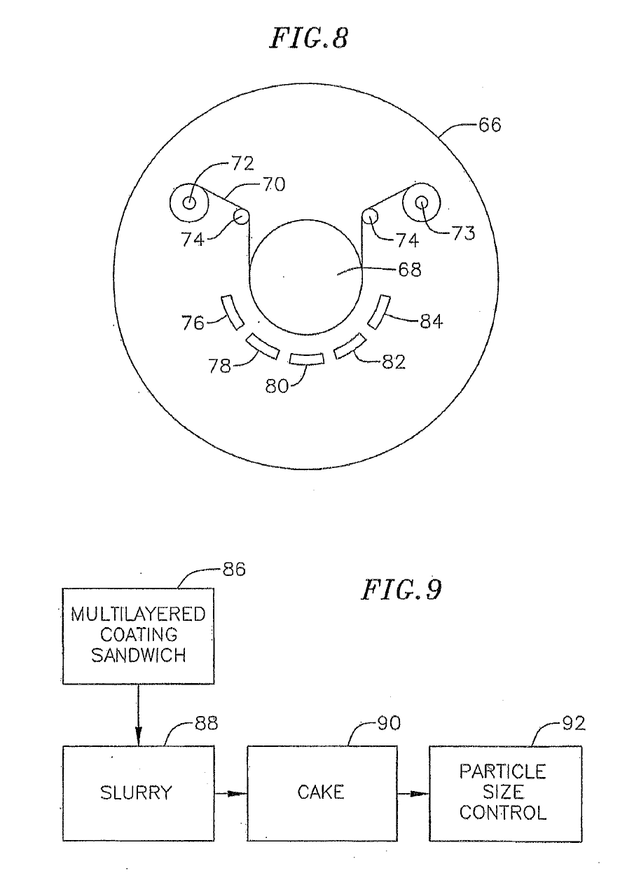

FIGS. 8 and 9 illustrate alternative embodiments for making the flakes illustrated in FIG. 6 or FIG. 7. With some embodiments as illustrated in FIG. 8, the process equipment includes a vapor deposition chamber 66, which contains a chilled rotating drum 68 and a flexible insoluble polyester carrier film 70 extending from a first reversible winding station 72 around a length of the drum's surface to a second reversible winding station 73. The length of wrap on the drum is controlled by two idle rollers 74. This vacuum chamber also includes a standard vacuum pump and an auxiliary turbo pump to maintain the vacuum level during coating operations. Rotation of the drum causes the polyester film to travel past a first release coat source 76, a first protective coating source 78, a metalizing source 80, a second protective coating source 82 and a second release coat source 84, in that order. Thus, as the drum rotates in a counterclockwise direction with respect to FIG. 8 the entire length of the polyester carrier is unwrapped from station 72 and taken up on station 73 after passing through the coating processes in sequence from sources 76, 78, 80, 82 and 84. The polyester carrier is then rewound by reversing the web path and inactivating the second release coating source 84 and then repeating the first step, but in a reverse (clockwise) direction so that the coatings are next applied from sources 82, 80, 78 and 76, in that order. The entire PET coated film is then taken up on station 72 and the sequence of steps is then repeated to build up layers on the film in the same sequence used to produce the multi-layer sandwich 38 of FIG. 4 (and the resulting coated metal flakes 32 of FIG. 7).

In accordance with some alternative embodiments, in which the single layer metal or glass flakes of FIG. 6 are produced, the multilayer sandwich 64 illustrated in FIG. 3 is built up on the polyester carrier 70 by inactivating the protective coating sources 78 and 82.

FIG. 9 illustrates, in accordance with some embodiments, processing of the multi-layered coating sandwich 86 built up on the polyester film, which is removed from the vacuum chamber 66 and introduced into an organic solvent stripping process at 88 to remove the sandwich material from the PET. The solvent is then subjected to centrifuging to produce a cake 90 of concentrated flakes which is later subjected to particle size control (homogenizing) at 92.

In accordance with some embodiments, suitable carriers on which the multi-layer sandwich material are deposited ensure that the deposits of thin layers are smooth and flat. Polyester films or other polymeric films having a high tensile strength and resistance to high temperature are used, along with metal drums, belts or plates which can be stainless steel or chrome plated, in accordance with some embodiments. In addition to or instead of drums, a support web or substrate is utilized with some embodiments.

In accordance with some embodiments of the invention and as previously described, polymeric release coats are applied for the purpose of facilitating later separation of the flake layers built up in the multi-layer sandwich material. Prior art use of cross-linked polymeric layers bonded between vapor deposited metal layers in a polymer/metal vapor deposition process inhibits later separation of the metalized layers into flakes. Polymerization of the polymeric layers such as by electron beam (EB) curing prevents subsequent re-dissolving of the polymeric layers and so the aluminum flake layers do not easily come apart.

In accordance with some embodiments of the present invention, the intervening polymeric layers are formed by vaporization and deposition while under vacuum in the vacuum deposition chamber. The polymeric release material is, with some embodiments, a flowable low viscosity, relatively low molecular weight, very clean, thermoplastic polymer or monomer, which is essentially free of any volatiles that would be evolved during the coating process. Such a material is not, with some embodiments, a blend of different polymeric materials including additives, solvents and the like. When the polymeric material is heated to its melt or coating or deposition temperature, continuous operation of the vacuum pump in the vacuum chamber is not adversely affected by volatiles. The release coat material, with some embodiments, promotes intercoat separation between alternating vacuum deposited metal or glass flake or multi-layer flake layers. The release layer accomplishes this objective, with some embodiments, by being dissolvable in a suitable organic solvent.

The release material also is metallizable, with some embodiments, and also requires sufficient adhesion to enable stack build-up on a rotating drum, as well as being electron beam (EB) vaporizable. The release coat material, in accordance with some embodiments, has a sufficiently high molecular weight or resistance to melting, such that it resists heat build up on the drum or other carrier without becoming flowable. Heat build up comes not only from the metal deposited on the release layer but also from operation of the deposition sources inside the chamber. The ability of the release coat to resist flowability can ensure, with some embodiments, that flakes with high brightness can be produced, because the release coat surface on which metal is deposited remains smooth. The release material, with some embodiments, is also capable of surviving the heat of electron beam (EB) deposition. The release material, with some embodiments, is not be a material, such as certain low molecular weight materials, which detrimentally affects vacuum pressure maintained in the chamber, which may cause the chamber to lose vacuum. Maintaining a minimum operating vacuum level in the chamber is required, with some embodiments, to maintain production speed without breaking the vacuum. During subsequent stripping and treatment with organic solvents, essentially all of the release coat material is removed from the flakes, with some embodiments. However, in the event that some small amount of release coat material remains on the flakes after the flake layers are broken down into particles, the system can withstand some residue from the release coat, particularly if, for example, the flakes are subsequently used in acrylic inks or paints or coating systems in which the flakes are compatible.

Referring to the non-limiting embodiment represented by FIG. 2, the multi-layer sandwich is made by applying the coatings directly to the rotating drum, and this is typically a desirable process because it has lower production costs than the process of coating a PET (polyethylene terephthalate) carrier. Each such cycle involves breaking the vacuum, taking out the sandwich layer for further processing outside the vacuum chamber, and re-charging (or re-establishing) the vacuum. The rate at which the process can be run, in building up layers, can vary from approximately 500 to 2,000 feet per minute. Metalizing only in the vacuum can operate at higher speeds.

In accordance with some embodiments, in which the single layer flakes are produced, the flakes can have high aspect ratios. This is attributed, in part, to the capability of cleanly removing the intervening release coat layers from the metalized flakes. With thermoset or cross-linked polymeric layers bonded in between the metal layers, the layers cannot be easily separated and resulting flakes have lower aspect ratios. In accordance with some embodiments, the process of the present invention produces single layer reflective aluminum flakes approximately 5 to 500 angstroms thick, and approximately 4 to 12 microns in particle size.

The release coat materials are applied in exceedingly thin layers preferably about 0.1 to about 0.2 microns for coated layers and about 100 to 400 angstroms for electron beam (EB) deposited layers.

In accordance with some embodiments in which the metal flakes are coated on opposite sides with the protective polymeric film layers, the protective coating layers are applied at a thickness of about 150 angstroms or less. The protective coating material, with some embodiments, is silicon dioxide, silicon monoxide, aluminum oxide, and combinations of two or more thereof. Further non-limiting examples of protective coatings include aluminum fluoride, magnesium fluoride, indium tin oxide, indium oxide, calcium fluoride, titanium oxide, sodium aluminum fluoride, and combinations of two or more thereof. With some embodiments, the protective coating is one which is compatible with the ink or coating system in which the flakes are ultimately used. Use of the protective coatings on the metal flakes, with some embodiments, reduces the aspect ratio of the finished flake product, although the aspect ratio of this multi-layer flake is still higher than the ratio for conventional flakes. However, such flakes are more rigid than the single layer flakes, and this rigidity provided by the clear glass-like coated metal flakes can, with some embodiments, make the coated flakes useful in fluidized bed chemical vapor deposition (CVD) processes for applying certain optical or functional coatings directly to the flakes. Optical vapor deposited (OVD) coatings are an example. Chemical vapor deposition (CVD) coatings can be added to the flakes for preventing the flakes from being prone to attack by other chemicals or water, in accordance with some embodiments. Colored flakes also can be produced with some embodiments, such as flakes coated with gold or iron oxide. Additional non-limiting uses for the coated flakes include, as moisture-resistant flakes in which the metal flakes are encapsulated in an outer protective coat, and in microwave active applications in which an encapsulating outer coat inhibits arcing (such as electrical arcing) from the metal flakes. The flakes also can be used in electrostatic coatings, with some embodiments.

In accordance with some alternative embodiments, the release coat layers include certain cross-linked resinous materials, such as an acrylic monomer cross-linked to a solid by exposure to actinic radiation, such as ultraviolet (UV) or electron beam (EB) curing. With such embodiments, the multi-layer sandwich is removed from the drum, or while on the carrier, it is treated with certain materials that de-polymerize the release coat layers such as by breaking the chemical bonds formed from the cross-linking material. This process allows use of conventional equipment utilizing vapor deposition and curing with electron beam (EB) or plasma techniques.

The processes described herein and in accordance with the present invention enable the production of reflective flakes at high production speeds and low cost. The uncoated flakes produced can have a high aspect ratio. Where aspect ratio is defined as the ratio of particle size (such as width or diameter) to thickness, and the average flake size is approximately 6 microns by 200 angstroms (one micron equals 10,000 angstroms), the aspect ratio 60,000/200 is or is about 300:1. This high aspect ratio is comparable to the METALURE® flakes described previously. With the embodiments in which flakes are coated on both sides with protective layers, the aspect ratio of these flakes is approximately, 60,000/600 or about 100:1.

In additional embodiments the dispersing additive is not added to the release agent but rather at any process stage starting from stripping until particle sizing. The dispersing additive may be added, for example, in the stripping chamber or to the pigment cake obtained after decantation.

In additional embodiments the dispersing additive may be even added after particle sizing. However, it has been found that best results can be obtained when adding the additiveat the beginning of the process to the release coat.

With some embodiments of the present invention, the flakes or platelets produced by the method of the present invention, and the flakes or platelets of dispersions containing such flakes or platelets according to the present invention, have a d50 particle size of 6 micrometers to 50 micrometers. In accordance with some further embodiments, effect pigments produced by the methods of the present invention, and the effect pigments of dispersions containing such effect pigments, have a d50 particle size of 6 micrometers to 50 micrometers. The d50 particle size in each case being as defined previously herein.

Embossed flake also can, with some embodiments, be made by the various methods described herein. In accordance with such embodiments, the carrier or deposition surface (such as a drum or polyester carrier) can be embossed with a pattern, such as, but not limited to, a holographic grating pattern or a diffraction grating pattern, or the like. The first release layer replicates the pattern, and subsequent metal or other layers and intervening release layers replicate the same pattern. The stack can be stripped and broken into embossed flakes. In further preferred embodiments, however, the pigments are non-embossed pigments.

In accordance with some embodiments of the present invention, there is provided one or more processes for speeding production of the flake products, which utilizes three side-by-side vacuum chambers separated by air locks. The middle chamber contains a drum and the necessary deposition equipment for applying the layers of flake material and release coats to the drum. After completion of the deposition cycle, the drum and coating are transferred to the vacuum chamber downstream from the deposition chamber, through an air lock, for maintaining the vacuum in both chambers. The middle chamber is then sealed off. A drum contained in the upstream chamber is then moved to the middle chamber for further deposition. This drum is moved through an air lock to maintain the vacuum in both chambers. The middle chamber is then sealed off. The coated drum in the downstream chamber is removed, stripped of its deposited layers, cleaned and replaced in (or re-introduced into) the upstream chamber. This process enables, with some embodiments, continuous coating in the middle vacuum chamber without breaking its vacuum.

Despite numerous advantages of the processes described herein for forming relatively small particles or flakes, frequently an undesirable quantity of larger particles or agglomerations of particles exist in the final product. For many applications, particles unable to pass through an 80 mesh screen are undesirable and thus are separated from other smaller particles, with some embodiments. Although performing such separation is technically feasible, such processing typically involves additional labor, time, equipment, and expense.

The polymeric release agent of the methods and effect pigments of the present invention can be selected from a wide variety of polymeric release agents. In accordance with some embodiments, the polymeric release agent is selected from at least one of polyvinyl alcohol, polyvinyl butyral, polyethylene glycol, (meth)acrylic polymers, polystyrene, poly(meth)acrylamide, cellulosic resins, polyvinyl butyral, modified nylon resins, cellulose acetate butyrate (CAB). Preferred polymeric release agents are (meth)acrylic resins, polystyrene and cellulosic resins.

In accordance with some embodiments of the present invention, it has been surprisingly discovered that the addition of one or more additives and/or dispersing agents to a release system (such as the previously noted release system sources 44, 76, and/or 84), results in a reduction of the proportion of large particles or agglomerations in a flake product that are unable to pass through an 80 mesh screen.

A variety of dispersants can be incorporated in the release systems as described herein in order to reduce the proportion of large particles or agglomerations in the flake product.

In accordance with some embodiments, the dispersing agent (or dispersant) is selected from at least one of:

(a) a sulfonic acid;
(b) a salt of a sulfonic acid;
(c) nonionic polyethers represented by the formula R₁-(EO)ₓ-(PO)_{y},

wherein R₁ is an a linear or non-linear C₆-C₅₀ alkyl, aryl, alkylaryl, arylalkyl residual, x is 3 to 50, and y is 0 to 50, wherein the order of EO and PO units is interchangeable;

(d) phosphoric acid esters represented by the formula (OH)₍₃₋ₙ₎PO(OR₂)ₙ; and
(e) phosphonic acid esters represented by the formula (OH)₍₃₋ₙ₎PO(R₂)ₙ,

wherein, n is 1 or 2, and each R₂ is independently a linear or branched alkyl, aryl or aralkyl radical containing at least 5 carbon atoms, and a radical of an oxyalkylated alcohol with a number average molecular weight between 100 and 5000 g/mole and/or a radical containing at least one carboxylic acid ester group and/or a urethane group with a number average molecular weight between 100 and 5000 g/mole.

In accordance with some preferred embodiments, the dispersing agent is a salt of a sulfonic acid represented by the following formula (I):

RSO₂—OH (I)

With reference to formula (I), R is selected from an alkyl group, an aryl group, and an alkyl-aryl group. The aryl group of the sulfonic acid can be selected from C₅-C₂₀ aryl groups, including fused ring aryl groups, such as, but not limited to, phenyl, naphthalenyl, anthracenyl, and phenanthrenyl. The aryl group is naphthalene (or naphthalenyl), with some embodiments. With some additional embodiments, each alkyl group is selected from linear alkyl groups and branched alkyl groups. With some further embodiments, the alkyl group is a C₅-C₂₀ linear, branched or cyclic alkyl group. In accordance with some embodiments, the alkyl group of the alkyl-aryl group is bonded directly to the —SO₂—OH portion of the sulfonic acid, and one or more aryl groups are bonded to the alkyl group. With some further embodiments, the aryl group of the alkyl-aryl group is bonded directly to the —SO₂—OH portion of the sulfonic acid, and one or more alkyl groups are bonded to the aryl group. The alkyl and aryl groups of the alkyl-aryl group can be selected, without limitation, from those classes and examples as described previously herein. The salt of the sulfonic acid is, with some embodiments, a calcium salt. With some further embodiments, other cations, ligands, or species are used as appropriate. The sulfonic acid of the dispersent, such as the sulfonic acid represented by formula (I) above, is in some instances referred to herein as an “alkyl and/or aryl sulfonic acid.”

In accordance with some embodiments, the dispersant is K-SPERSE 131 dispersing agent, which is commercially available from King Industries of Norwalk, Conn. K-SPERSE 131 is a dispersing agent containing a calcium salt of an alkyl and/or aryl sulfonic acid dissolved in an aliphatic solvent.

The salt of the sulfonic acid represented by formula (I), with some embodiments, includes a cation selected the following group:

an imidazolium represented by the following formula,

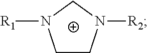

a phosphonium represented by the following formula,

^{\textcircled{+}} P(R₁R₂R₃R₄);

an ammonium represented by the following formula,

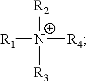

a pyrazolium, represented by the following formula,

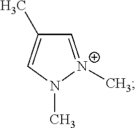

a pyridinium represented by the following formula,

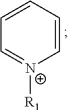

a pyrrolidinium represented by the following formula,

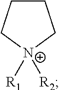

and
a sulfonium, represented by the following formula,

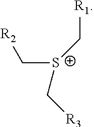

With the above representative formulas of the cations, R₁, R₂, R₃, and R₄ are each independently a C₁-C₄₀ hydrocarbyl group, in each case optionally interrupted with at least one heteroatom, (such as O, N, S, and P). The term “hydrocarbyl group” includes linear or branched alkyl, cycloalkyl (including fused ring cyclic alkyl and polycyclic alkyl), and aromatic (including fused ring aromatic).

The release system, in accordance with some embodiments, includes one or more solvents that are selected from the solvents and solvent families listed in Table 1 below.

TABLE 1
Solvents for Release Systems

| Solvent | CAS # |
|---|---|
| Acetone | 67-64-1 |
| Ethyl Alcohol | 64-17-5 |
| Isopropanol | 67-63-0 |
| Ethyl Acetate | 141-78-6 |
| Isopropyl Acetate | 108-21-4 |
| n-Propyl Acetate | 109-60-4 |
| Propylene Glycol Monomethyl Ether | 107-98-2 |
| 3-Methoxy 3-Methyl 1-Butanol | 56539-66-3 |
| n-Butoxyethanol | 111-76-2 |
| Propylene Glycol Monomethyl Ether | 108-65-6 |
| Acetate | |
| Dimethyl Carbonate | 616-38-6 |
| Ketones | — |
| Ester solvents | — |
| Glycol Ethers | — |
| Alcohols | — |

With some embodiments, the solvent or mixture of solvents of the effect pigment dispersions of the present invention, is/are present in an amount of at least 70 percent by weight, based on total weight of the effect pigment dispersion. With some further embodiments, the solvent or mixture of solvents of the effect pigment dispersions of the present invention, is/are present in an amount of from 70 percent by weight to 96 percent by weight, or from 70 percent by weight to 75 percent by weight, in each case the percent weights being based on total weight of the effect pigment dispersion.

In accordance with some embodiments of the present invention, the release systems include: (i) one or more of the solvents listed in Table 1; (ii) a suitable polymeric system, selected from, for example, styrene polymers, acrylic resins or blends thereof, as previously described herein; and (iii) one or more dispersants which are, with some embodiments salts of a sulfonic acid represented by formula (I). With some embodiments, the release system utilizes one or more polymers. With some further embodiments, the release system alternatively includes at least one non-polymeric release agent instead of one or more polymeric release agents. In accordance with some further embodiments, the release systems also include additional components such as optional crosslinking agents, additives, and/or other components. The various components in the release systems can be used in any effective concentrations. The concentration of the dispersant(s) is, with some embodiments, from about 0.25% to about 5% by weight of the release system (based on total weight of the release system). However, it will be appreciated that the invention includes the use of dispersant concentrations in greater or lesser amounts.

A significant advantage of using one or more dispersants in accordance with some embodiments of the methods according to the present invention described herein is improved control over particle size and particle size distribution in the final product. Use of the dispersant(s) in conjunction with some embodiments of the present invention, reduces the amount and/or proportion of undesirable large particles or flakes that can cause failure or detrimentally impact downstream operations.

In accordance with some embodiments of the present invention, it has also been surprisingly discovered that when forming flakes from multi-layer sandwich constructions, such as those formed from the process represented by FIG. 5, multi-layer sandwich constructions having only two metal layers are preferred relative to multi-layer sandwich constructions having 3 or more layers of metal. Thus, although in general increasing the number of layers of metal leads to increased yield of product, with some embodiments, this is countered by detrimental effects upon quality of the produced flakes or particles. Thus, for with some embodiments, formation of a two layer metal intermediate is preferred over a layered configuration having a greater number of layers.

In accordance with some embodiments of the invention, it has also been surprisingly discovered that the use of a vibratory sieve operating at particular parameters, significantly improves the quality of the final flake product. With some embodiments, use of a vibratory sieve (such as during a particle size control operation 24 in FIG. 1, operation 62 in FIG. 5 and/or operation 92 in FIG. 9), has been found to produce a more desirable product. Although not intending to be limited by any particular theory, it is believed, based on the evidence at hand, that the use of a vibratory sieve reduces particle or flake agglomeration and leads to a narrower distribution of particles or flakes of desired sizes. With some embodiments, the vibratory sieve is used in conjunction with a screening or filter screening assembly and imparts a vibration or oscillating motion to the screen through which the particle or flake product passes. In accordance with some embodiments, the frequency of such vibration is from about 10 to about 60 Hz, such as about 30 Hz.

All of the various strategies, aspects and embodiments described herein can be used and/or practiced as desired. In accordance with some embodiments of the methods of the present invention, the dispersants of formula (I) are used in combination with (i) forming two metal layers in a layered assembly during flake production, (ii) using a vibratory sieve during product screening, and (iii) combinations of (i) and (ii).

Additional details and aspects concerning the various methods and flakes are described in one or more of the following US patents: U.S. Pat. Nos. 7,820,088; 6,863,851; 6,666,995; 6,398,999; 6,153,288; 6,068,691; 5,672,410; 5,650,248; 5,624,076; and 3,949,139.

Many other benefits will no doubt become apparent from future application and development of this technology.

All patents, published applications, and articles noted herein are hereby incorporated by reference in their entirety.

The present invention relates to various non-limiting embodiments as described previously herein and in accordance with the following.

In accordance with a first non-limiting embodiment of the present invention, there is provided a method for producing metal flakes, platelets, and/or particles, in which the method comprises providing a substrate; applying a release system to the substrate, the release system comprising (i) solvent, (ii) at least one release agent, and (iii) a dispersant, to thereby form a release layer; applying a metal layer to the release layer; removing the metal layer; and subjecting the removed metal to one or more particle size control operations to thereby produce the metal flakes, platelets, and/or particles. The sulfonic acid, of the salt of the sulfonic acid of the dispersant, with some embodiments, comprises an alkyl group, an aryl group, or an alkyl-aryl group.

In accordance with a second non-limiting embodiment of the method of the present invention, the dispersing agent is a salt of a sulfonic acid, wherein the sulfonic acid comprises an alkyl group, an aryl group, or an alkyl-aryl group

In accordance with a third non-limiting embodiment of the method of the present invention, the sulfonic acid is represented by the following formula (I):

RSO₂—OH (I)

wherein R is selected from an alkyl group, an aryl group, and an alkyl-aryl group, wherein each alkyl group is selected from linear alkyl groups and branched alkyl groups.

In accordance with a fourth non-limiting embodiment of the present invention, the aryl group of the sulfonic acid represented by formula (I) is naphthalene.

In accordance with a fifth non-limiting embodiment of the method of the present invention, the salt of the sulfonic acid is a calcium salt.

In accordance with a sixth non-limiting embodiment of the method of the present invention, the solvent of the release system is selected from the group consisting of acetone, ethyl alcohol, isopropanol, ethyl acetate, isopropyl acetate, n-propyl acetate, propylene glycol monomethyl ether, 3-methoxy 3-methyl 1-butanol, n-butoxyethanol, propylene glycol monomethyl ether acetate, dimethyl carbonate, ketones, ester solvents, glycol ethers, alcohols, and combinations thereof.

In accordance with a seventh non-limiting embodiment of the method of the present invention, the dispersant is present in an amount of 0.25% to 5% based on total weight of the release system.

In accordance with an eighth non-limiting embodiment of the method of the present invention, the polymeric release agent is selected from at least one of polyvinyl alcohol, polyvinyl butyral, polyethylene glycol, (meth)acrylic polymers, polystyrene, polyacrylamide, cellulosic resins, polyvinyl butyral, modified nylon resins, cellulose acetate butyrate (CAB).

In accordance with a ninth non-limiting embodiment of the method of the present invention, the release system further comprises a crosslinking agent for the polymeric release agent.

In accordance with a tenth non-limiting embodiment of the method of the present invention, the release system further comprises an additive.

In accordance with an eleventh non-limiting embodiment of the method of the present invention, the method further comprises, after applying a metal layer and prior to removing, applying another layer on the metal layer, followed by applying a second metal layer.

In accordance with a twelfth non-limiting embodiment of the method of the present invention, subjecting the removed metal to one or more particle size control operations, comprises passing the removed metal through a screen undergoing oscillatory movement.

In accordance with a thirteenth non-limiting embodiment of the method of the present invention, the oscillatory movement is conducted at a frequency of from 10 Hz to 60 Hz.

In accordance with a fourteenth non-limiting embodiment of the method of the present invention, the oscillatory movement is conducted at a frequency of 30 Hz.

In accordance with a fifteenth non-limiting embodiment of the method of the present invention, the substrate is a drum.

In accordance with a sixteenth non-limiting embodiment of the method of the present invention, the substrate is a support web.

In accordance with a seventeenth non-limiting embodiment of the present invention, there is provided a metal flake, platelet, or particle product that is produced by the method as described above.

In accordance with an eighteenth non-limiting embodiment of the present invention, there is provided an effect pigment dispersion that comprises, (a) an effect pigment, present in an amount of 4 to 25 percent by weight, based on total weight of the effect pigment dispersion. The effect pigment has a form selected from flake forms, platelet forms, and/or particle forms. The effect pigment dispersion further comprises, (b) residues of a polymeric release layer comprising: (i) a release agent, present in an amount of 1 to 15 percent by weight, based on total weight of said effect pigment; and (ii) a dispersing agent, present in an amount of 0.025 to 1.5 percent by weight, based on total weight of said effect pigment. The effect pigment dispersion further comprises, (c) a solvent, or mixture of solvents, present in an amount providing a balance of 100 percent by weight, based on total weight of said effect pigment dispersion.

In accordance with further non-limiting embodiments of the effect pigment dispersion of the present invention, the various components thereof, such as, but not limited to, the release agent, the dispersing agent, the solvent, and optional additives, are each as described previously herein, and can be selected from one or more classes and examples as described previously herein with regard to the method of the present invention.

In accordance with a nineteenth non-limiting embodiment of the effect pigment dispersion of the present invention, the dispersing agent is selected from at least one of,

(a) a sulfonic acid
(b) a salt of a sulfonic acid,
(c) nonionic polyethers represented by the formula R₁-(EO)ₓ-(PO)_{y},

wherein R₁ is an a linear or non-linear C₆-C₅₀ alkyl, aryl, alkylaryl, arylalkyl residual, x is 3 to 50, and y is 0 to 50, wherein the order of EO and PO units is interchangeable,

(d) phosphoric acid esters represented by the formula (OH)₍₃₋ₙ₎PO(OR₂)ₙ, and
(e) phosphonic acid esters represented by the formula (OH)₍₃₋ₙ₎PO(R₂)ₙ,

wherein, n is 1 or 2, and each R₂ is independently a linear or branched alkyl, aryl or aralkyl radical containing at least 5 carbon atoms, and a radical of an oxyalkylated alcohol with a number average molecular weight between 100 and 5000 g/mole and/or a radical containing at least one carboxylic acid ester group and/or a urethane group with a number average molecular weight between 100 and 5000 g/mole.

In accordance with a twentieth non-limiting embodiment of the present invention, the dispersing agent, of the effect pigment dispersion, is a salt of a sulfonic acid, in which the sulfonic acid comprises an alkyl group, an aryl group, or an alkyl-aryl group, further wherein each alkyl group is selected from linear alkyl groups and branched alkyl groups.

In accordance with a twenty-first non-limiting embodiment of the present invention, the dispersing agent, of the effect pigment dispersion, is a salt of a sulfonic acid, in which the sulfuric acid is represented by the following formula (I):

RSO₂—OH (I)

wherein R is selected from an alkyl group, an aryl group, and an alkyl-aryl group, further wherein each alkyl group is selected from linear alkyl groups and branched alkyl groups.

In accordance with a twenty-second non-limiting embodiment of the effect pigment dispersion of the present invention, the aryl group, of the sulfonic acid represented by formula (I), is naphthalene.

In accordance with a twenty-third non-limiting embodiment of the effect pigment dispersion of the present invention, the polymeric release agent is selected from at least one of polyvinyl alcohol, polyvinyl butyral, polyethylene glycol, (meth)acrylic polymers, polystyrene, polyacrylamide, cellulosic resins, polyvinyl butyral, modified nylon resins, cellulose acetate butyrate (CAB).

In accordance with a twenty-fourth non-limiting embodiment of the effect pigment dispersion of the present invention, the polymeric release agent is selected from at least one of (meth)acrylic resins, polystyrene and cellulosic resins.

In accordance with a twenty-fifth non-limiting embodiment of the present invention, the effect pigment, of the effect pigment dispersion, is present in an amount of from 5 to 20 percent by weight, based on total weight of said effect pigment dispersion.

In accordance with a twenty-sixth non-limiting embodiment of the present invention, the effect pigment, of the effect pigment dispersion, is a metal effect pigment comprising a metal selected from the group consisting of aluminum, copper, silver, chromium, nickel, tin, zinc, iron, indium, combinations of two or more thereof, and alloys of two or more thereof.

In accordance with a twenty-seventh non-limiting embodiment of the present invention, the effect pigment, of the effect pigment dispersion, is a non-metal effect pigment comprising a non-metal material selected from the group consisting of magnesium fluoride, zinc sulfide, zinc oxide, silicon dioxide, silicon monoxide, silicon suboxide, aluminum oxide, aluminum fluoride, indium tin oxide, titanium dioxide, and combinations of two or more thereof.

In accordance with a twenty-eighth non-limiting embodiment of the present invention, the solvent, of the effect pigment dispersion, comprises at least one of acetone, ethyl alcohol, isopropanol, ethyl acetate, isopropyl acetate, n-propyl acetate, propylene glycol monomethyl ether, 3-methoxy 3-methyl 1-butanol, n-butoxyethanol, propylene glycol monomethyl ether acetate, dimethyl carbonate.

In accordance with a twenty-ninth non-limiting embodiment of the present invention, the solvent, of the effect pigment dispersion, is present in an amount of at least 70 percent by weight, based on total weight of said effect pigment dispersion.

In accordance with a thirtieth non-limiting embodiment of the present invention, the effect pigment, of the effect pigment dispersion, has a d50 of 6 micrometers to 50 micrometers, in which the d50 value is the cumulative frequency distribution of the volume-averaged size distribution function. The particle size distribution is preferably measured using laser granulometry, most preferably with a Cilas 1064 instrument. The particle sizes are calculated using Fraunhofer theory and assuming spheric shape. The d50-value means that 50% of the particles measured (calculated as volume averaged) are below this value.

In accordance with a thirty-first non-limiting embodiment of the present invention, there is provided a use of the effect pigments prepared by the methods of the present invention in coatings, printing inks or nail varnishes.

In accordance with a thirty-second non-limiting embodiment of the present invention, there is provided a use of the effect pigment dispersions of the present invention in screen printing inks.

The present invention is more particularly described in the following examples, which are intended to be illustrative only, since numerous modifications and variations therein will be apparent to those skilled in the art. Unless otherwise specified, all parts and all percentages are by weight.

### EXAMPLES

### Comparative Example 1

### Commercially Available Metalure®-Pigment Dispersion

An aluminum pigment was made in the following manner. A release coat comprising 10% polystyrene in toluene was coated onto a ½ mil thick PET carrier sheet with a 200 line quad rotogravure roll on a commercial roll coater and dried, leaving a glossy film of polystyrene on the carrier sheet. The coated carrier sheet was then metallized on a Vacuum Roll Coater applying 300 angstroms of thickness of aluminum film. In a roll-to-roll process against release coat was gravure coated and than metallized. This sequence was further repeated twice leading to a stack of four release coat/aluminium foil stacks. This metallized, coated carrier sheet was then passed through a stripping machine containing acetone as solvent. A slurry of aluminum flakes was collected having a concentration of about 1% by weight of aluminum flakes. The slurry was subjected to ultrasonic treatment and was centrifuged afterwards leaving a cake of concentrated aluminium flakes at a concentration of about 50 wt-%. The aluminum flake cake was the diluted with ethyl acetate under homogenisation to obtain a suspension with a concentration of about 10% solids. Than the suspension was subjected to particle sizing using a Ultra Turrax T45 leading to particles with a d50 of 10 μm (measured by Cilas 1064).

Analysis revealed that the suspension contained about 8 wt.-% residual polystyrene, referred to the metal content.

### Example 1

The procedure of Comparable Example 1 was repeated, except that to the release coat dispersion was first added the dispersant K-SPERSE 131 (King Industries Norwalk, Conn.) and homogenized. The amount of additive was 30 wt-% of polystyrene.

### Comparative Example 2

### According to Example 1 of U.S. Pat. No. 7,820,088 B2

The following multi-layer construction was made: release layer/metal/release layer. The release layer was Dow 685D extrusion grade styrene resin and the metal layer was aluminum from Materials Research Corp. 90101E-AL000-3002.

The construction was repeated 50 times, i.e., alternating layers of aluminum and styrene release coats.

The styrene used in the release layer was conditioned as follows:
The styrene pellets were melted and conditioned in a vacuum oven at 210° C. for 16 hours and then removed to a desiccator to cool.
An aluminum foil lined graphite crucible was used to hold this material.
This crucible was placed in a copper lined Arco
Temiscal single pocket electron beam gun hearth.

The aluminum pellets were melted into a copper lined Arco Temiscal four-pocket electron beam gun hearth.

The electron beam guns were part of a 15 KV Arco Temiscal 3200 load-lock system. Two mil PET film from SKC was cut into three seventeen inch diameter circles and attached to seventeen inch diameter stainless steel planetary discs located in the vacuum chamber. The chamber was closed and roughed to ten microns then cryopumped to a vacuum of 5×10-7 Torr.

The release and metal material were vapor deposited in alternating layers. The release layer was deposited first at 200 angstroms as measured by a Inficon IC/5 deposition controller. The release layer was followed by a metal layer vapor deposited at 160 angstroms also measured by the IC/5 controller. The controller for the aluminum layer was calibrated by a MacBeth TR927 transmission densitometer with green filter. As mentioned, this construction was repeated 50 times. The vapor deposited aluminum layer had a good thickness of 1.8 to 2.8 optical density as measured by a MacBeth densitometer. This value measures metal film opacity, via a light transmission reading.

When the deposition was complete, the chamber was vented with nitrogen to ambient pressure and the PET discs removed. The discs were washed with ethyl acetate and were then homogenized using a IKA Ultra Turrax T45 to reach a particle size d50 of about 8 microns, measured with Cilas 1064.

### Example 2

The styrene resin was dissolved in toluene by heating and stirring. The dispersant K-SPERSE 131 was added and homogenized. The amount of additive was 30 wt-% of polystyrene.

The solvent was stripped off under vacuum and the remaining dispersion was dried for five hours under vacuum. The resulting polystyrol granulate was used in the procedure of

### Comparative Example 2

### Screening Tests

All metal pigment dispersions were subjected to a screening test as follows:

15 g of the Pigment dispersion were mixed with 45 g butyl glycol and homogenized for about 1 min using a paint brush. A 80 mesh sieve of plastics (Sefar Nitex 03-80/37) having a diameter of 90 mm was clamped in a suitable ring. The pigment dispersion was poured over the sieve. Remaining suspension was washed with acetone and also poured over the sieve. The pigment residue not passing the sieve was centralized and it's amount was quantified by optical visualization. The results are depicted in table 2:

TABLE 2
Evaluation of residual pigment agglomerates after sieving.

| | Amount of residual |
|---|---|
| Probe | after sieving (80 mesh) |
| Comparative Example 1 | High |
| Example 1 | Very low |
| Comparative Example 2 | High |
| Example 2 | Very low |

The residuals were analysed analytically with respect to their content of polystyrene and unusual high concentrations of about 30-40 wt.-% were found. Thus the agglomerates merely have been generated from agglomerates of metal particles with the residual release coat in the pigment dispersion.

The inventive process leads to aluminium flake dispersions with much less agglomerates and therefore to more economical process.

### Screening Printing Tests:

All pigment dispersions of the examples and comparative examples were further processed to produce screen printing inks using a formulation of commercially available Ultra Star SX9200 (Eckart GmbH). The pigment concentration was 6 percent by weight in all cases.

All Screen printing inks were printed on a Roko Print using a sieve of 100 mesh. 25 Prints were done for each probe and the prints were visualized for pin-holes. Example 1 and 2 revealed quality with no pin-holes whereas Comparative Example 2 revealed a still acceptable quality with a few pin holes. Comparative Example 2 revealed a not acceptable quality with a rather many pin holes.

As described hereinabove, the present invention solves many problems associated with previously known processes. However, it will be appreciated that various changes in the details, materials and arrangements of components and/or operations, which have been herein described and illustrated in order to explain the nature of the invention, may be made by those skilled in the art without departing from the principle and scope of the invention, as expressed in the appended claims.

1. A method for producing metal flakes, platelets, and/or particles, the method comprising:
providing a substrate;
applying a release system to the substrate, the release system comprising,
(i) solvent,
(ii) at least one polymeric release agent, and
(iii) a dispersing agent,
to thereby form a release layer;
applying a metal layer to the release layer;
removing the metal layer; and
subjecting the removed metal to one or more particle size control operations to thereby produce the metal flakes, platelets, and/or particles.

2. The method of claim 1, wherein said dispersing agent is a salt of a sulfonic acid, wherein said sulfonic acid comprises an alkyl group, an aryl group, or an alkyl-aryl group.

3. The method of claim 2, wherein said sulfonic acid is represented by the following formula (I):
RSO₂—OH (I)
wherein R is selected from an alkyl group, an aryl group, and an alkyl-aryl group, wherein each alkyl group is selected from linear alkyl groups and branched alkyl groups.

4. The method of claim 2 wherein the aryl group is naphthalene.

5. The method of claim 2, wherein the salt of said sulfonic acid is a calcium salt.

6. The method of claim 1, wherein the solvent is selected from the group consisting of acetone, ethyl alcohol, isopropanol, ethyl acetate, isopropyl acetate, n-propyl acetate, propylene glycol monomethyl ether, 3-methoxy 3-methyl 1-butanol, n-butoxyethanol, propylene glycol monomethyl ether acetate, dimethyl carbonate, ketones, ester solvents, glycol ethers, alcohols, and combinations thereof.

7. The method of claim 1, wherein said dispersant is present in an amount of 0.25% to 5% based on total weight of the release system.

8. The method of claim 1, wherein said polymeric release agent is selected from at least one of polyvinyl alcohol, polyvinyl butyral, polyethylene glycol, (meth)acrylic polymers, polystyrene, polyacrylamide, cellulosic resins, polyvinyl butyral, modified nylon resins, cellulose acetate butyrate (CAB).

9. (canceled)

10. (canceled)

11. The method of claim 1, further comprising:
after applying a metal layer and prior to removing, applying another layer on the metal layer, followed by applying a second metal layer.

12.-15. (canceled)

16. The method of claim 1, wherein the substrate is a support web.

17. (canceled)

18. An effect pigment dispersion comprising:
a) an effect pigment, present in an amount of 4 to 25 percent by weight, based on total weight of said effect pigment dispersion, said effect pigment having a platelet form;
b) residues of a release layer comprising,
i) a polymeric release agent, present in an amount of 1 to 15 percent by weight, based on total weight of said effect pigment, and
ii) a dispersing agent, present in an amount of 0.025 to 1.5 percent by weight, based on total weight of said effect pigment; and
c) a solvent or mixture of solvents, present in an amount providing a balance of 100 percent by weight, based on total weight of said effect pigment dispersion.

19. The effect pigment dispersion of claim 18, wherein the dispersing agent is selected from at least one of,
(a) a sulfonic acid
(b) a salt of a sulfonic acid,
(c) nonionic polyethers represented by the formula R₁-(EO)ₓ-(PO)_{y},
wherein R₁ is an a linear or non-linear C₆-C₅₀ alkyl, aryl, alkylaryl, arylalkyl residual, x is 3 to 50, and y is 0 to 50, wherein the order of EO and PO units is interchangeable,
(d) phosphoric acid esters represented by the formula (OH)₍₃₋ₙ₎PO(OR₂)ₙ, and
(e) phosphonic acid esters represented by the formula (OH)₍₃₋ₙ₎PO(R₂)ₙ,
wherein, n is 1 or 2, and each R₂ is independently a linear or branched alkyl, aryl or aralkyl radical containing at least 5 carbon atoms, and a radical of an oxyalkylated alcohol with a number average molecular weight between 100 and 5000 g/mole and/or a radical containing at least one carboxylic acid ester group and/or a urethane group with a number average molecular weight between 100 and 5000 g/mole.

20. The effect pigment dispersion of claim 19, wherein said dispersing agent is said salt of said sulfonic acid, wherein said sulfonic acid comprises an alkyl group, an aryl group, or an alkyl-aryl group, wherein each alkyl group is selected from linear alkyl groups and branched alkyl groups.

21. The effect pigment dispersion of claim 20, wherein said sulfonic acid is represented by the following formula (I):
RSO₂—OH (I)
wherein R is selected from an alkyl group, an aryl group, and an alkyl-aryl group, wherein each alkyl group is selected from linear alkyl groups and branched alkyl groups.

22. (canceled)

23. The effect pigment dispersion of claim 18, wherein said polymeric release agent is selected from at least one of polyvinyl alcohol, polyvinyl butyral, polyethylene glycol, (meth)acrylic polymers, polystyrene, poly(meth)acrylamide, cellulosic resins, polyvinyl butyral, modified nylon resins, cellulose acetate butyrate (CAB).

24. (canceled)

25. The effect pigment dispersion of claim 18, wherein said effect pigment is present in an amount of from 5 to 20 percent by weight, based on total weight of said effect pigment dispersion.

26. The effect pigment dispersion of claim 18, wherein said effect pigment is a metal effect pigment comprising a metal selected from the group consisting of aluminum, copper, silver, chromium, nickel, tin, zinc, iron, indium, combinations of two or more thereof, and alloys of two or more thereof.

27. (canceled)

28. The effect pigment dispersion of claim 18, wherein said solvent comprises at least one of acetone, ethyl alcohol, isopropanol, ethyl acetate, isopropyl acetate, n-propyl acetate, propylene glycol monomethyl ether, 3-methoxy 3-methyl 1-butanol, n-butoxyethanol, propylene glycol monomethyl ether acetate, dimethyl carbonate.

29. The effect pigment dispersion of claim 18, wherein said solvent is present in an amount of at least 70 percent by weight, based on total weight of said effect pigment dispersion.

30. (canceled)

31. A coating, printing ink, or nail varnish comprising an effect pigment prepared according to the method of claim 1.

32. (canceled)
